(19) United States
(12) Patent Application Publication
(10) Pub. No.: US 2024/0081068 A1
(43) Pub. Date: Mar. 7, 2024

(54) SEMICONDUCTOR DEVICE AND METHOD OF MANUFACTURING THE SAME

(71) Applicant: RENESAS ELECTRONICS CORPORATION, Tokyo (JP)

(72) Inventors: Akio ONO, Tokyo (JP); Hiraku CHAKIHARA, Tokyo (JP)

(21) Appl. No.: 18/344,413

(22) Filed: Jun. 29, 2023

(30) Foreign Application Priority Data
Sep. 5, 2022 (JP) 2022-140807

(51) Int. Cl. H10B 43/30

(52) U.S. Cl. CPC H10B 43/30

(57) ABSTRACT

A control gate electrode is formed on a semiconductor substrate via a first gate dielectric film. A second gate dielectric film including a charge storage layer is formed on an upper surface of the semiconductor substrate and on one side surface of the control gate electrode. A memory gate electrode is formed on the second gate dielectric film. A cap film formed of a dielectric material is formed on an upper surface of the control gate electrode, and a silicide film is formed on an upper surface of the memory gate electrode. An upper surface of the cap film and an upper surface of the silicide film are exposed from a sidewall spacer SW and an interlayer dielectric film.

### CROSS-REFERENCE TO RELATED APPLICATIONS

The disclosure of Japanese Patent Application No. 2022-140807 filed on Sep. 5, 2022, including the specification, drawings and abstract is incorporated herein by reference in its entirety.

### BACKGROUND

The present disclosure relates to a semiconductor device and a method of manufacturing the same, and more particularly, to a technique applicable to a semiconductor device including a nonvolatile memory cell.

In recent years, an electrically programmable and erasable nonvolatile memory cell is included in a semiconductor device. As an exemplary nonvolatile memory cell, a MONOS (Metal-Oxide-Nitride-Oxide-Semiconductor) type transistor having a trapping dielectric film surrounded by oxide films under a gate electrode of MISFET (Metal Insulator Semiconductor Field Effect Transistor) is used. A split-gate type memory cell in which the MONOS transistor is used as a memory transistor and a control transistor is further added is known.

There are disclosed techniques listed below.
[Patent Document 1] Japanese Unexamined Patent Application Publication No. 2017-139375
[Patent Document 2] Japanese Unexamined Patent Application Publication No. 2014-154665

Patent Document 1 discloses a semiconductor device including a split-gate type memory cell and a MISFET for logic circuit. A gate electrode of the MISFET for the logic circuit includes a metal film formed using a gate last process. A silicide film is formed on an upper surface of a memory gate electrode of the memory transistor and on an upper surface of a control gate electrode of the control transistor.

Patent Document 2 discloses a split-gate type memory cell formed using a gate first process. In this memory cell, a silicide film is formed on the upper surface of the memory gate electrode, but a dielectric film is formed on the upper surface of the control gate electrode, and no silicide film is formed on the upper surface of the control gate electrode.

### SUMMARY

When the gate electrode of the MISFET for the logic circuit is formed by using a gate last process as in the semiconductor device of Patent Document 1, a polishing process is performed by a CMP (Chemical Mechanical Polishing) method. Since the polishing process is performed also in a region where the nonvolatile memory cell is formed, the positions of upper surfaces of the memory gate electrode and the control gate electrode become substantially the same. In this state, a silicide film is formed on the upper surface of each of the memory gate electrode and the control gate electrode.

Since a gate dielectric film including a charge storage layer is present between the memory gate electrode and the control gate electrode, the memory gate electrode and the control gate electrode are insulated from each other. However, in a step of forming the silicide film, there is a problem that the silicide film may grow abnormally, and there is a problem that a residue may remain on the gate dielectric film located between the memory gate electrode and the control gate electrode. Due to these problems, a short-circuit defect may occur between the memory gate electrode and the control gate electrode.

A main purpose of the present application is to suppress the occurrence of the short-circuit defect between the memory gate electrode and the control gate electrode, and to improve the reliability of the semiconductor device.

Other objects and novel features will become apparent from the description of this specification and the accompanying drawings.

The typical ones of the embodiments disclosed in the present application will be briefly described as follows.

In one embodiment, a semiconductor device includes: a first gate dielectric film formed on an upper surface of a semiconductor substrate; a first gate electrode formed on the first gate dielectric film; a second gate dielectric film formed on the upper surface of the semiconductor substrate and on one side surface of the first gate electrode and including a charge storage layer; a second gate electrode formed on the second gate dielectric film such that one side surface of the second gate electrode faces the one side surface of the first gate electrode via the second gate dielectric film; a first sidewall spacer formed on the other side surface of the first gate electrode; a first interlayer dielectric film formed on the other side surface of the first gate electrode via the first sidewall spacer; a second sidewall spacer formed on the other side surface of the second gate electrode; a second interlayer dielectric film formed on the other side surface of the second gate electrode via the second sidewall spacer. A cap film formed of a dielectric material is formed on an upper surface of one of the first gate electrode and the second gate electrode, and a silicide film is formed on an upper surface of the other of the first gate electrode and the second gate electrode. An upper surface of the cap film and an upper surface of the silicide film are exposed from the first sidewall spacer, the second sidewall spacer, the first interlayer dielectric film and the second interlayer dielectric film.

In one embodiment, a method of manufacturing a semiconductor device includes: (a) forming a first gate dielectric film on an upper surface of a semiconductor substrate; (b) forming a first gate electrode on the first gate dielectric film; (c) forming a first cap film formed of a dielectric material on the first gate electrode; (d) forming a second gate dielectric film on the upper surface of the semiconductor substrate, on a side surface of the first gate electrode and on a side surface of the first cap film, the second gate dielectric film including a charge storage layer; (e) forming a second gate electrode on the second gate dielectric film so as to be adjacent to the first gate electrode and the first cap film via the second gate dielectric film; (f) forming an interlayer dielectric film on the upper surface of the semiconductor substrate so as to cover the first cap film and the second gate electrode; (g) performing a polishing process to the interlayer dielectric film, the first cap film and the second gate electrode, thereby exposing an upper surface recessed by the polishing process of each of the first cap film and the second gate electrode from the interlayer dielectric film; and (h) after the (g), forming a silicide film on the upper surface of the second gate electrode in a state where the first cap film remains.

In one embodiment, a method of manufacturing a semiconductor device includes: (a) forming a first gate dielectric film on an upper surface of a semiconductor substrate; (b) forming a first gate electrode on the first gate dielectric film; (c) forming a first cap film formed of a dielectric material on the first gate electrode; (d) forming a second gate dielectric film on the upper surface of the semiconductor substrate, on a side surface of the first gate electrode and on a side surface of the first cap film, the second gate dielectric film including a charge storage layer; (e) forming a second gate electrode and a second cap film on the second gate dielectric film so as to be adjacent to the first gate electrode and the first cap film via the second gate dielectric film, the second cap film being located on the second gate electrode and formed of a dielectric material; (f) forming an interlayer dielectric film on the upper surface of the semiconductor substrate so as to cover the first cap film and the second cap film; (g) performing a polishing process to the interlayer dielectric film, the first cap film, the first gate electrode and the second cap film, thereby removing the first cap film and exposing an upper surface recessed by the polishing process of each of the first gate electrode and the second cap film from the interlayer dielectric film; and (h) after the (g), forming a silicide film on the upper surface of the first gate electrode in a state where the second cap film remains.

According to one embodiment, the reliability of the semiconductor device can be improved.

### BRIEF DESCRIPTION OF THE DRAWINGS

FIG. 1 is a plan view showing a layout of a semiconductor device in a first embodiment.

FIG. 2 is a cross-sectional view showing the semiconductor device in the first embodiment.

FIG. 3 is a cross-sectional view showing a manufacturing method of the semiconductor device in the first embodiment.

FIG. 4 is a cross-sectional view showing the manufacturing method of the semiconductor device following FIG. 3.

FIG. 5 is a cross-sectional view showing the manufacturing method of the semiconductor device following FIG. 4.

FIG. 6 is a cross-sectional view showing the manufacturing method of the semiconductor device following FIG. 5.

FIG. 7 is a cross-sectional view showing the manufacturing method of the semiconductor device following FIG. 6.

FIG. 8 is a cross-sectional view showing the manufacturing method of the semiconductor device following FIG. 7.

FIG. 9 is a cross-sectional view showing the manufacturing method of the semiconductor device following FIG. 8.

FIG. 10 is a cross-sectional view showing the manufacturing method of the semiconductor device following FIG. 9.

FIG. 11 is a cross-sectional view showing the manufacturing method of the semiconductor device following FIG. 10.

FIG. 12 is a cross-sectional view showing the manufacturing method of the semiconductor device following FIG. 11.

FIG. 13 is a cross-sectional view showing the manufacturing method of the semiconductor device following FIG. 12.

FIG. 14 is a cross-sectional view showing the manufacturing method of the semiconductor device following FIG. 13.

FIG. 15 is a cross-sectional view showing the manufacturing method of the semiconductor device following FIG. 14.

FIG. 16 is a cross-sectional view showing the manufacturing method of the semiconductor device following FIG. 15.

FIG. 17 is a cross-sectional view showing the manufacturing method of the semiconductor device following FIG. 16.

FIG. 18 is a cross-sectional view showing the manufacturing method of the semiconductor device following FIG. 17.

FIG. 19 is a cross-sectional view showing a semiconductor device in a second embodiment.

FIG. 20 is a cross-sectional view showing a manufacturing method of the semiconductor device in the second embodiment.

FIG. 21 is a cross-sectional view showing the manufacturing method of the semiconductor device following FIG. 20.

FIG. 22 is a cross-sectional view showing the manufacturing method of the semiconductor device following FIG. 21.

FIG. 23 is a cross-sectional view showing the manufacturing method of the semiconductor device following FIG. 22.

FIG. 24 is a cross-sectional view showing the manufacturing method of the semiconductor device following FIG. 23.

FIG. 25 is a cross-sectional view showing the manufacturing method of the semiconductor device following FIG. 24.

FIG. 26 is a cross-sectional view showing the manufacturing method of the semiconductor device following FIG. 25.

FIG. 27 is a cross-sectional view showing the manufacturing method of the semiconductor device following FIG. 26.

FIG. 28 is a cross-sectional view showing the manufacturing method of the semiconductor device following FIG. 27.

FIG. 29 is a cross-sectional view showing the manufacturing method of the semiconductor device following FIG. 28.

FIG. 30 is a cross-sectional view showing the manufacturing method of the semiconductor device following FIG. 29.

FIG. 31 is a cross-sectional view showing the manufacturing method of the semiconductor device following FIG. 30.

FIG. 32 is a cross-sectional view showing the manufacturing method of the semiconductor device following FIG. 31.

FIG. 33 is a cross-sectional view showing the manufacturing method of the semiconductor device following FIG. 32.

FIG. 34 is a cross-sectional view showing the manufacturing method of the semiconductor device following FIG. 33.

### DETAILED DESCRIPTION

Hereinafter, embodiments will be described in detail based on the drawings. In all the drawings for explaining the embodiments, members having the same functions are denoted by the same reference numerals, and repetitive descriptions thereof are omitted. In the following embodiments, descriptions of the same or similar parts will not be repeated in principle except when particularly necessary.

### First Embodiment

### Structure of Semiconductor Device

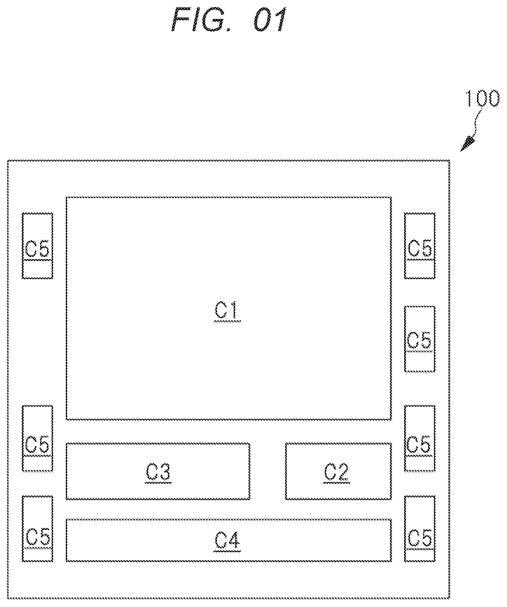

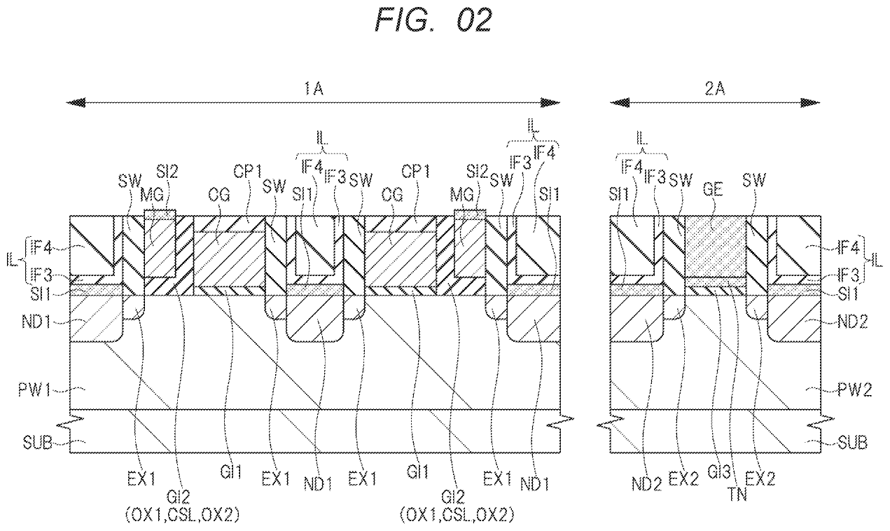

A semiconductor device 100 in the first embodiment will be described below with reference to FIGS. 1 and 2.

FIG. 1 shows a planar layout of the semiconductor device 100 and shows an exemplary arrangement of circuits C1 to C5. As shown in FIG. 1, the semiconductor chip 100 includes a nonvolatile memory circuit C1, a CPU (Central Processing Unit) circuit C2, a RAM (Random Access Memory) circuit C3, an analog circuit C4, and an I/O (Input/Output) circuit C5.

The nonvolatile memory C1 includes an EEPROM and a flash memory which are electrically programmable and erasable. In the nonvolatile memory C1, a split-gate type memory cell including, for example, a MONOS transistor is formed as a semiconductor element.

The CPU circuit C2 includes a logic circuit that is driven at a voltage of about 1.5 V. In the CPU circuit C2, a low breakdown voltage MISFET having a low breakdown voltage and a high operation speed is formed as a semiconductor element. The RAM circuit C3 includes a SRAM (Static RAM). In the RAM circuit C3, a low breakdown voltage MISFET having substantially the same configuration as that in the CPU circuit C2 is formed as a semiconductor element. In the analog circuit C4, a high breakdown voltage MISFET having a breakdown voltage higher than that of the low breakdown voltage MISFET and being driven at a voltage of about 6 V, a capacitive element, a resistive element, a bipolar transistor, and the like are formed as semiconductor elements. The I/O circuit C5 includes an input/output circuit. In the I/O circuit C5, a high breakdown voltage MISFET substantially similar to that in the analog circuit C4 is formed as a semiconductor element.

The semiconductor elements configuring the circuits C1 to C5 are formed in the same semiconductor substrate SUB. The semiconductor substrate SUB includes regions for forming these elements. FIG. 2 shows a region 1A in which a nonvolatile memory cell is formed and a region 2A in which an n-type low breakdown voltage MISFET is formed.

As shown in FIG. 2, the nonvolatile memory cell in the first embodiment is a split-gate type memory cell including a memory transistor and a control transistor. The control transistor includes a gate dielectric film GI1 and a control gate electrode CG. The memory transistor includes a gate dielectric film GI2 and a memory gate electrode MG. The nonvolatile memory cell in the first embodiment further includes an extension region EX1, a diffusion region ND1, a silicide film SI1, a silicide film SI2, and a cap film CP1.

The low breakdown voltage MISFET includes a gate dielectric film GI3, a metal film TN, a gate electrode GE, an extension region EX2, a diffusion region ND2, and the silicide film SI1.

The semiconductor substrate SUB is made of, for example, p-type silicon. A p-type well region PW1 is formed in the semiconductor substrate SUB in the region 1A, and a p-type well region PW2 is formed in the semiconductor substrate SUB in the region 2A. The well region PW1 and the well region PW2 are spaced apart from each other.

First, the configuration of the nonvolatile memory cell in the region 1A will be described.

The gate dielectric film GI1 is formed on an upper surface of the semiconductor substrate SUB. The gate dielectric film GI1 is, for example, a silicon oxide film, and has a thickness of, for example, 2 nm or more and 5 nm or less. The control gate electrode CG is formed on the gate dielectric film GI1. The control gate electrode CG is, for example, an n-type polycrystalline silicon film. The cap film CP1 is formed on the control gate electrode CG. The cap film CP1 is formed of a dielectric material, and is, for example, a silicon nitride film.

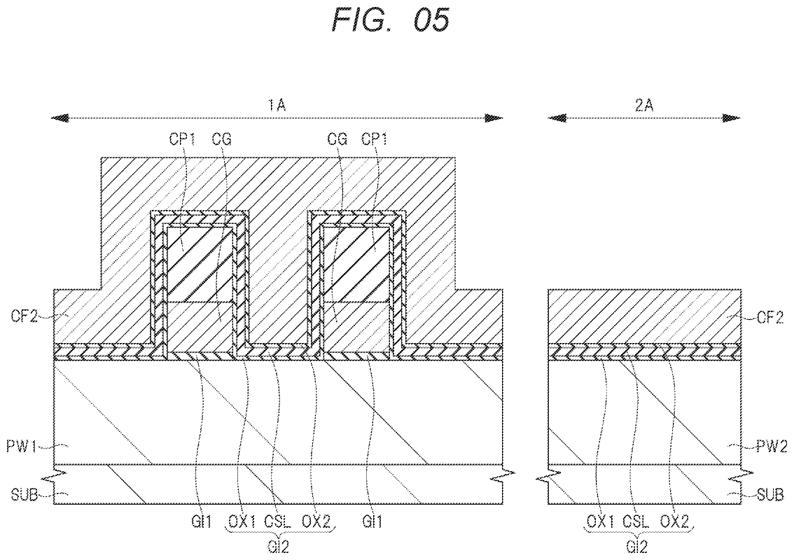

The gate dielectric film GI2 is formed on the upper surface of the semiconductor substrate SUB and on one side surface of the control gate electrode CG. The gate dielectric film GI2 includes, for example, a dielectric film OX1, a charge storage layer CSL formed on the dielectric film OX1, and a dielectric film OX2 formed on the charge storage layer CSL, and is formed of a stacked film of these films (see FIG. 5 described later). The dielectric film OX1 is, for example, a silicon oxide film, and has a thickness of, for example, 2 nm or more and 5 nm or less. The charge storage layer CSL is formed of a trapping dielectric film, for example, a silicon nitride film, and has a thickness of, for example, 5 nm or more and 8 nm or less. The charge storage layer CSL may be a high dielectric constant dielectric film having a dielectric constant higher than that of the silicon nitride film. The dielectric film OX2 is, for example, a silicon oxide film, and has a thickness of, for example, 2 nm or more and 5 nm or less.

The memory gate electrode MG is formed on the gate dielectric film GI2. The memory gate electrode MG is, for example, an n-type polycrystalline silicon film. The silicide film SI2 is formed on an upper surface of the memory gate electrode MG. The silicide film SI2 is formed of, for example, nickel silicide (NiSi), nickel platinum silicide (NiPtSi), or cobalt silicide (CoSi₂).

The memory gate electrode MG is adjacent to the control gate electrode CG via the gate dielectric film GI2. In other words, one side surface of the memory gate electrode MG faces one side surface of the control gate electrode CG via the gate dielectric film GI2.

A sidewall spacer SW is formed on the other side surface of the control gate electrode CG and the other side surface of the memory gate electrode MG, respectively, and an interlayer dielectric film IL is formed on each of the side surface via the sidewall spacer SW. The sidewall spacer SW is, for example, a silicon nitride film or a silicon oxide film, or a stacked film thereof. The interlayer dielectric film IL is a stacked film of a dielectric film IF3 and a dielectric film IF4 formed on the dielectric film IF3. The dielectric film IF3 is, for example, a silicon nitride film, and the dielectric film IF4 is, for example, a silicon oxide film.

In the semiconductor substrate SUB (well region PW1), the n-type extension region EX1 and the n-type diffusion region ND1 are formed. The extension region EX1 is located under the sidewall spacer SW. The diffusion region ND1 is formed from the upper surface of the semiconductor substrate SUB to a position deeper than the extension region EX1, and has a higher impurity concentration than that of the extension region EX1. The extension region EX1 and the diffusion region ND1 which are formed on the side of the control gate electrode CG form a part of a drain region of the nonvolatile memory cell. The extension region EX1 and the diffusion region ND1 which are formed on the side of the memory gate electrode MG form a part of a source region of the nonvolatile memory cell.

The silicide film SI1 is formed on the diffusion region ND1. An upper surface of the silicide film SI1 is covered with the interlayer dielectric film IL. The silicide film SI1 is formed of, for example, nickel silicide (NiSi), nickel platinum silicide (NiPtSi), or cobalt silicide (CoSi₂).

Next, the configuration of the low breakdown voltage MISFET in the region 2A will be described.

The gate dielectric film GI3 is formed on the upper surface of the semiconductor substrate SUB. The gate dielectric film GI3 is, for example, a silicon oxide film, and has a thickness of, for example, 1 nm or more and 5 nm or less. The gate dielectric film GI3 may be a stacked film of a silicon oxide film and a high dielectric constant film formed on the silicon oxide film. The high dielectric constant film has a dielectric constant higher than that of the silicon nitride film, and is, for example, a hafnium oxide film (HfO₂ film), a hafnium silicate film (HfSiO film), a zirconium oxide film (ZrO₂ film), an aluminum oxide film (Al₂O₃ film), a tantalum oxide film (Ta₂O₅ film), or a lanthanum oxide film (La₂O₃ film).

The gate electrode GE is formed on the gate dielectric film GI3 via the metal film TN. The metal film TN functions as a part of the gate electrode GE, and is, for example, a titanium nitride film or a tantalum nitride film. The gate electrode GE includes a metal film. The metal film included in the gate electrode GE is, for example, an aluminum film, a titanium film, a titanium nitride film, a tantalum film, a tantalum nitride film, or a tungsten nitride film, or a stacked film obtained by appropriately stacking these films.

The sidewall spacer SW is formed on each of side surfaces of the gate electrode GE, and the interlayer dielectric film IL is formed on each of the side surfaces via the sidewall spacer SW. The film structures and the materials configuring the sidewall spacer SW and the interlayer dielectric film IL are the same as those in the region 1A.

In the semiconductor substrate SUB (well region PW2), the n-type extension region EX2 and the n-type diffusion region ND2 are formed. The extension region EX2 is located under the sidewall spacer SW. The diffusion region ND2 is formed from the upper surface of the semiconductor substrate SUB to a position deeper than the extension region EX1 and has a higher impurity concentration than that of the extension region EX2. The extension region EX2 and the diffusion region ND2 configure a part of a source region or a part of a drain region of the low breakdown voltage MISFET, respectively.

The silicide film SI1 is formed on the diffusion region ND2. The upper surface of the silicide film SI1 is covered with the interlayer dielectric film IL. The silicide film SI1 is formed of the same material as that in the region 1A.

### Main Features of First Embodiment

The main features of the first embodiment will be described in detail later in a manufacturing method of the semiconductor device, but in the first embodiment, a polishing process using a CMP method is performed to the memory gate electrode MG, the sidewall spacer SW, the interlayer dielectric film IL, and the cap film CP1. Therefore, these upper surfaces are located at substantially the same height and are flush with each other. The silicide film SI2 is formed on the memory gate electrode MG, for example, the positions of the upper surfaces of the respective sidewall spacers SW, the respective interlayer dielectric films IL, the cap film CP1, and the silicide film SI2 align with one another within a range of 10 nm or less. For example, when the position of the upper surface of the sidewall spacer SW is the highest and the position of the upper surface of the silicide film SI2 is the lowest, the difference between the position of the upper surface of the sidewall spacer SW and the position of the upper surface of the silicide film SI2 is 10 nm or less.

In addition, although the cap film CP1, the silicide film SI2, and the gate electrode GE are originally covered with the interlayer dielectric film IL, the respective upper surfaces are exposed from the respective sidewall spacers SW and the respective interlayer dielectric film IL by the polishing process.

In the prior art, the silicide film SI2 is formed on each of the upper surfaces of the control gate electrode CG and the memory gate electrode MG in a state where the upper surfaces are exposed by the polishing process. However, since these upper surfaces are located at substantially the same height, an abnormal growth of the silicide film SI2 and residues on the gate dielectric film GI2 during the step of forming the silicide film SI2 may cause a short-circuit defect between the control gate electrode CG and the memory gate electrode MG.

In the first embodiment, the silicide film SI2 is formed on the memory gate electrode MG, and the cap film CP1 formed of the dielectric material is formed on the control gate electrode CG. Therefore, a short-circuit defect between the control gate electrode CG and the memory gate electrode MG can be suppressed, and the reliability of the semiconductor device 100 can be improved.

### Manufacturing Method of Semiconductor Device

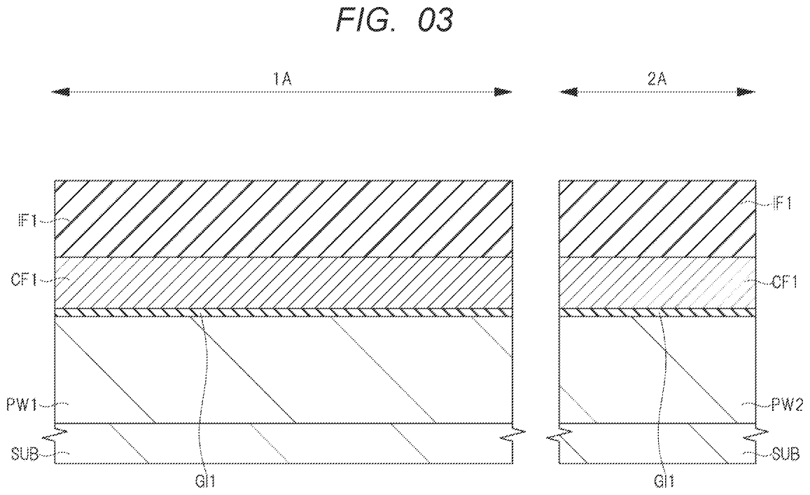

The respective manufacturing steps included in the manufacturing method of the semiconductor device 100 in the first embodiment will be described below with reference to FIGS. 3 to 18.

As shown in FIG. 3, first, the semiconductor substrate SUB is prepared. Next, the p-type well region PW1 is formed in the semiconductor substrate SUB in the region 1A and the p-type well region PW2 is formed in the semiconductor substrate SUB in the region 2A using a photolithography technique and an ion implantation method. Next, in the region 1A and the region 2A, the gate dielectric film GI1 is formed on the upper surface of the semiconductor substrate SUB using, for example, a thermal oxidation method.

Next, a conductive film CF1 for the control gate electrode CG is formed on the gate dielectric film GI1 using, for example, a CVD (Chemical Vapor Deposition) method. The conductive film CF1 is an n-type polycrystalline silicon film. Next, a dielectric film IF1 for the cap film CP1 is formed on the conductive film CF1 using, for example, the CVD method. At this time, a thickness of the conductive film CF1 is 80 nm or more and 100 nm or less. A thickness of the dielectric film IF1 is greater than the thickness of the conductive film CF1 and is 120 nm or more and 150 nm or less.

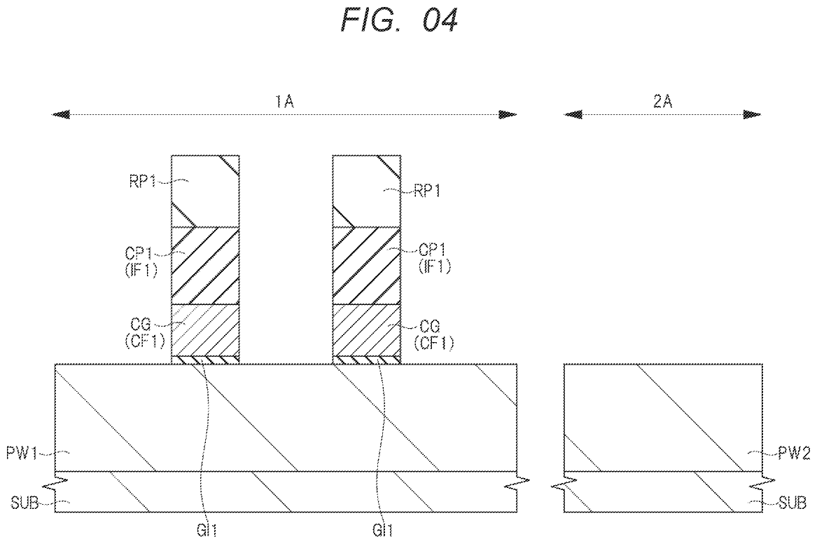

As shown in FIG. 4, first, a resist pattern RP1 is formed on the dielectric film IF1. The resist pattern RP1 covers a part of the region 1A and exposed another region. Next, the dielectric film IF1, the conductive film CF1, and the gate dielectric film GI1 are patterned by performing an etching process using the resist pattern RP1 as a mask.

The patterned dielectric film IF1 functions as the cap film CP1, and the patterned conductive film CF1 functions as the control gate electrode CG. Thereafter, the resist pattern RP1 is removed by an ashing process.

As shown in FIG. 5, in the region 1A, the gate dielectric film GI2 is formed on a side surface of the gate dielectric film GI1, on a side surface of the control gate electrode CG, on a side surface of the cap film CP1, on an upper surface of the cap film CP1, and on the upper surface of the semiconductor substrate SUB. At this time, the gate dielectric film GI2 is also formed on the upper surface of the semiconductor substrate SUB in the region 2A. In a step of forming the gate dielectric film GI2, first, the dielectric film OX1 is formed using a thermal oxidation method or the CVD method. Next, the charge storage layer CSL is formed on the dielectric film OX1 using the CVD method or an ALD (Atomic Layer Deposition) method. Next, the dielectric film OX2 is formed on the charge storage layer CSL using the CVD method.

Next, in the region 1A and the region 2A, a conductive film CF2 for the memory gate electrode MG is formed on the gate dielectric film GI2 using, for example, the CVD method. The conductive film CF2 is an n-type polycrystalline silicon film.

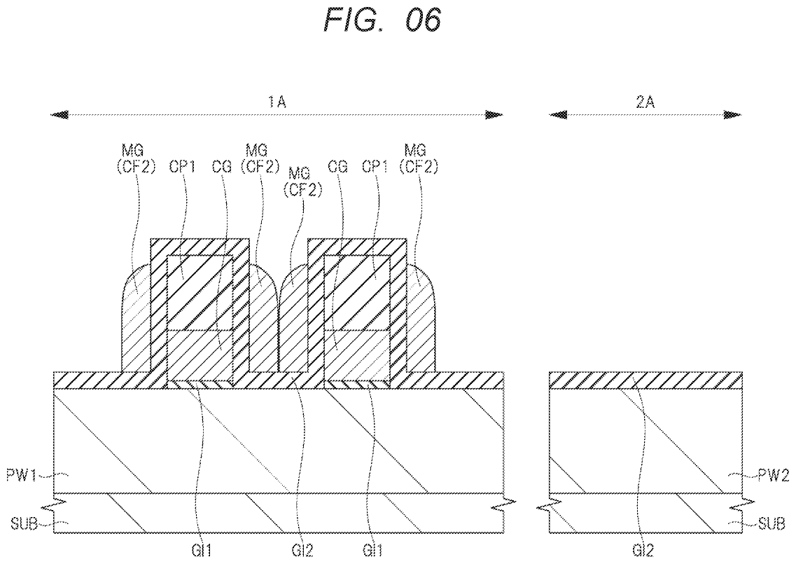

As shown in FIG. 6, an anisotropic etching process is performed to the conductive film CF2 to form the sidewall-shaped memory gate electrode MG in the region 1A. The memory gate electrode MG is formed on the gate dielectric film GI2 so as to be adjacent to the control gate electrode CG and the cap film CP1 via the gate dielectric film GI2. All the conductive film CF2 in the region 2A is removed.

Since the sidewall-shaped memory gate electrode MG remains on the side surface of the stacked body formed of the control gate electrode CG and the cap film CP1 by the anisotropic etching process, the position of the upper surface of the memory gate electrode MG can be increased. At this time, a position of a boundary between the control gate electrode CG and the cap film CP1 is lower than the position of the upper surface of the memory gate electrode MG.

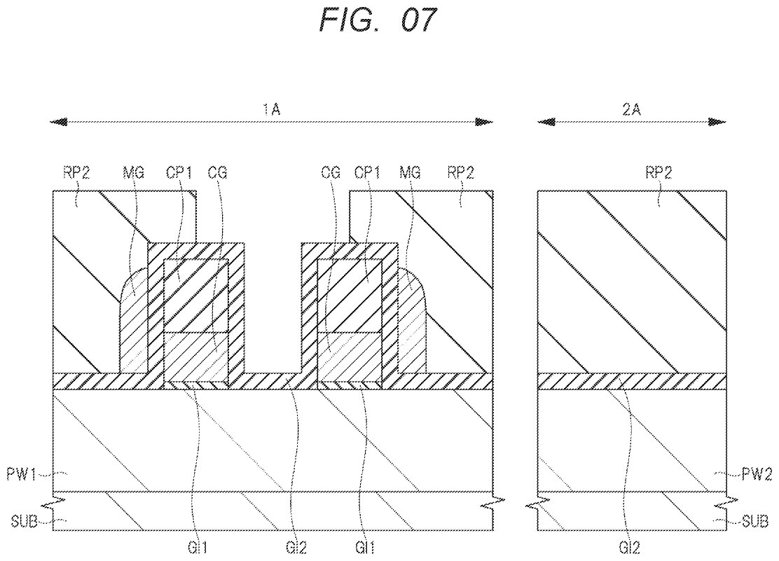

As shown in FIG. 7, first, a resist pattern RP2 covering a part of the region 1A and the region 2A is formed. In the region 1A, the resist pattern RP2 covers the memory gate electrode MG formed on one side surface of the control gate electrode CG and exposes the memory gate electrode MG formed on the other side surface of the control gate electrode CG.

Next, the memory gate electrode MG formed on the other side surface of the control gate electrode CG is removed by performing an etching process using the resist pattern RP2 as a mask. One side surface of the control gate electrode CG and one side surface of the remaining memory gate electrode MG face each other via the gate dielectric film GI2. Thereafter, the resist pattern RP2 is removed by an ashing process.

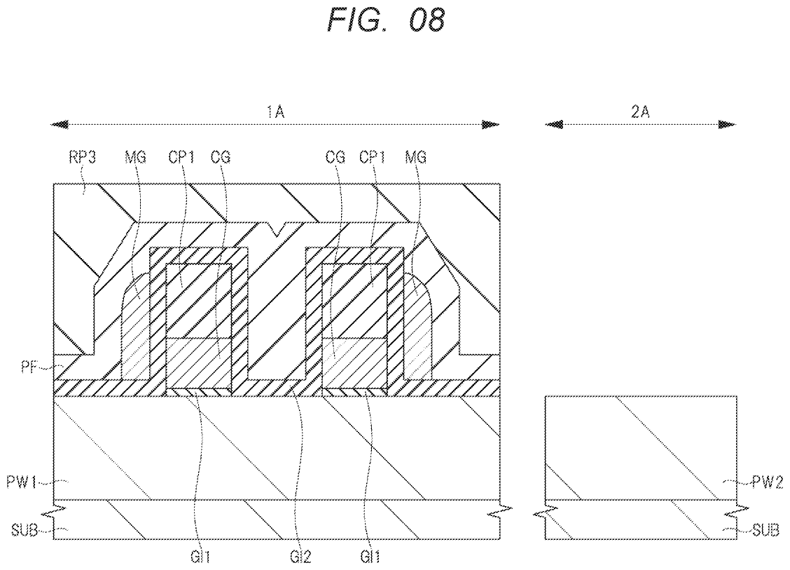

As shown in FIG. 8, a protective film PF is formed on the gate dielectric film GI2 so as to cover the memory gate electrode MG using, for example, the CVD method. The protective film PF is, for example, a dielectric film such as a silicon nitride film. Next, a resist pattern RP3 is formed on the protective film PF. The resist pattern RP3 covers the region 1A and exposed the region 2A. Next, the protective films PF and the gate dielectric film GI2 in the region 2A are removed by performing an etching process using the resist pattern RP3 as a mask. Thereafter, the resist pattern RP3 is removed by ashing.

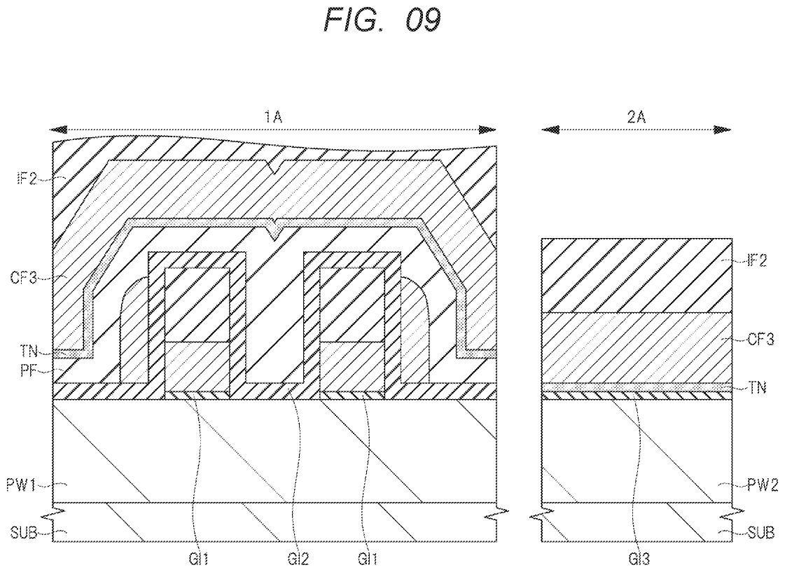

As shown in FIG. 9, first, the gate dielectric film GI3 is formed on the upper surface of the semiconductor substrate SUB in the region 2A using, for example, the thermal oxidation method. Next, the metal film TN and a conductive film CF3 for a gate pattern GP are sequentially formed on the protective film PF in the region 1A and the gate dielectric film GI3 in the region 2A using, for example, the CVD method. The conductive film CF3 is an n-type polycrystalline silicon film. Next, a dielectric film IF2 for a cap film CP3 is formed on the conductive film CF3 using, for example, the CVD method. At this time, a thickness of the conductive film CF3 is 120 nm or more and 150 nm or less. A thickness of the dielectric film IF2 is smaller than the thickness of the conductive film CF3, and is 80 nm or more and 100 nm or less.

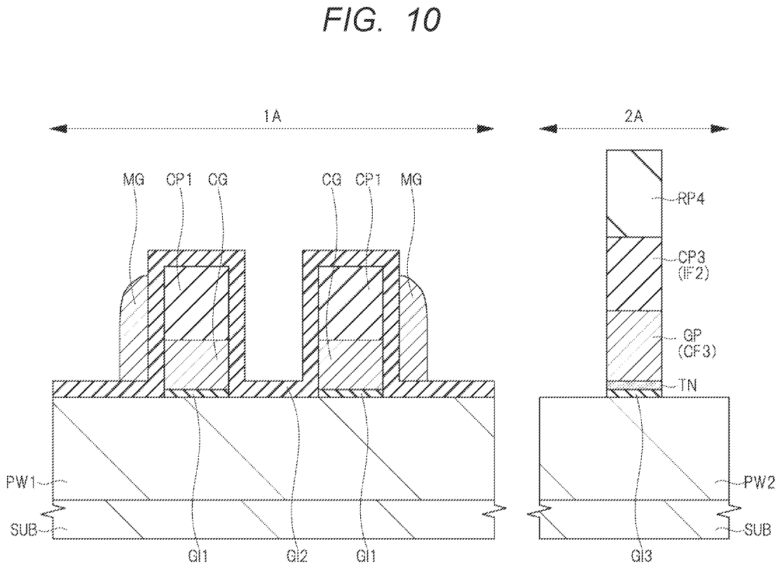

As shown in FIG. 10, first, a resist pattern RP4 is formed on the dielectric film IF2. The resist pattern RP4 covers a part of the region 2A and exposes another region. Next, the dielectric film IF2, the conductive film CF3, the metal film TN, and the gate dielectric film GI3 are patterned by performing an etching process using the resist pattern RP4 as a mask.

The patterned dielectric film IF2 functions as the cap film CP3, and the patterned conductive film CF3 functions as the gate pattern GP. The patterned metal film TN is a part of the gate electrode GE described later. At this time, in the region 1A, the dielectric film IF2, the conductive film CF3, the metal film TN, and the protective film PF are removed. Thereafter, the resist pattern RP4 is removed by ashing. The gate pattern GP is formed such that a position of an upper surface of the gate pattern GP is higher than the position of the boundary between the control gate electrode CG and the cap film CP1. Thus, when the upper surface of the gate pattern GP is exposed using the polishing process described later, the upper surface of the control gate electrode CG is not exposed.

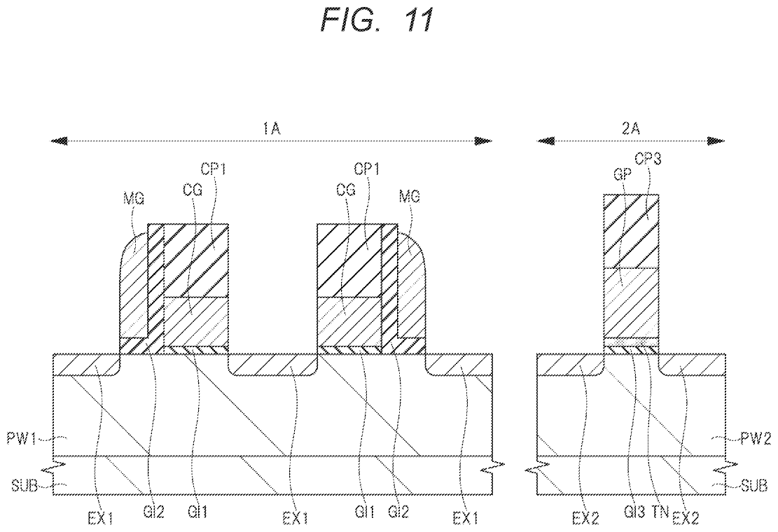

As shown in FIG. 11, first, the gate dielectric film GI2 not covered with the memory gate electrode MG is removed by an etching process. At this time, the gate dielectric film GI2 formed between the memory gate electrode MG and the control gate electrode CG remains.

Next, the n-type extension region EX1 is formed in the semiconductor substrate SUB (well region PW1) in the region 1A, and the n-type extension region EX2 is formed in the semiconductor substrate SUB (well region PW2) in the region 2A, by the photolithography technique and the ion implantation method. The extension region EX1 is formed at a position aligned with the memory gate electrode MG or the control gate electrode CG. The extension region EX2 is formed at a position aligned with the gate pattern GP.

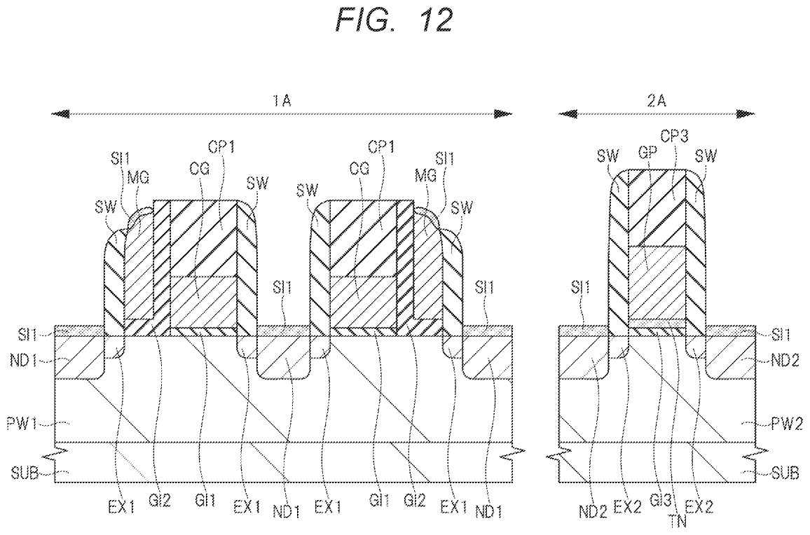

As shown in FIG. 12, the sidewall spacer SW is formed on the other side surface of the control gate electrode CG, on the other side surface of the memory gate electrode MG, and on each of, the side surfaces of the gate pattern GP. First, a dielectric film is formed so as to cover the region 1A and the region 2A using, for example, the CVD method. Next, the sidewall spacer SW can be formed by performing an anisotropic etching process to the dielectric film.

Next, the n-type diffusion region ND1 is formed in the semiconductor substrate SUB (well region PW1) in the region 1A, and the n-type diffusion region ND2 is formed in the semiconductor substrate SUB (well region PW2) in the region 2A, using the photolithography technique and the ion implantation method. The diffusion region ND1 and the diffusion region ND2 are formed at positions aligned with the sidewall spacers SW.

Next, the low-resistance silicide film SI1 is formed on the upper surface of each of the diffusion region ND1, the diffusion region ND2, and the memory gate electrode MG using a Salicide (Self Aligned Silicide) technique. Specifically, the silicide film SI1 can be formed as follows. First, a metal film for the silicide film SI1 is formed so as to cover the diffusion region ND1, the diffusion region ND2, and the memory gate electrode MG. The metal film is formed of, for example, nickel, nickel platinum, or cobalt. Next, a first heat process at about 300 to 400° C. and a second heat process at about 600 to 700° C. are performed to the metal film to react the materials contained in the diffusion region ND1, the diffusion region ND2, and the memory gate electrode MG with the metal film. As a result, the silicide film SI1 is formed. Thereafter, the unreacted metal film is removed.

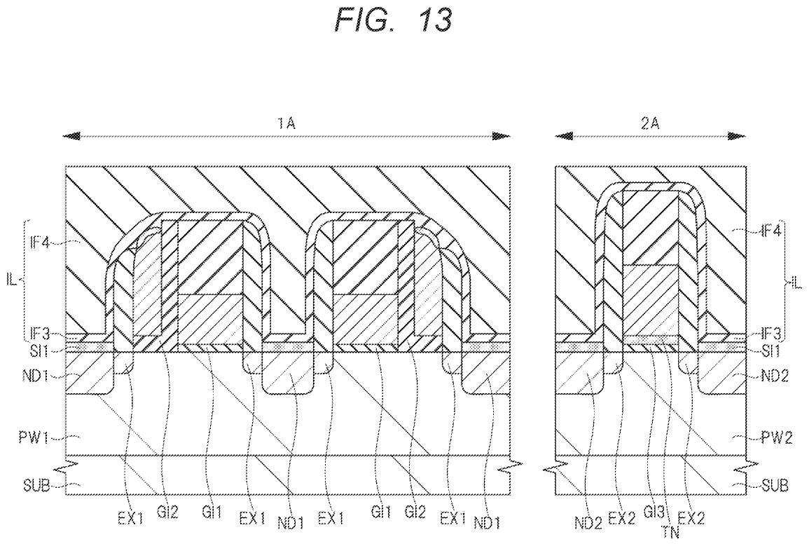

As shown in FIG. 13, the interlayer dielectric film IL is formed on the upper surface of the semiconductor substrate SUB so as to cover the cap film CP1, the memory gate electrode MG, the gate pattern GP, and the sidewall spacers SW. First, the dielectric film IF3 is formed on the upper surface of the semiconductor substrate SUB using, for example, the CVD method. Next, the dielectric film IF4 is formed on the dielectric film IF3 using, for example, the CVD method. The dielectric film IF3 and the dielectric film IF4 configure the interlayer dielectric film IL.

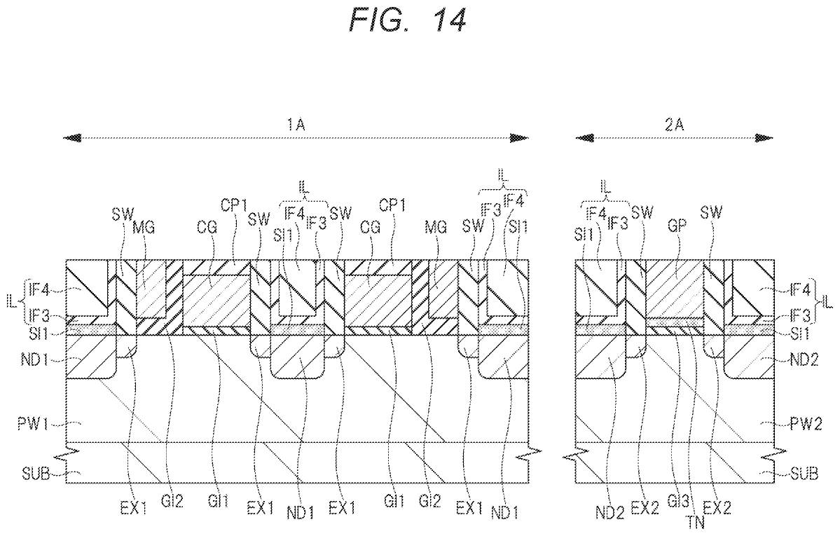

As shown in FIG. 14, the polishing process using the CMP method is performed to the interlayer dielectric film IL, the cap film CP1, the memory gate electrode MG, the cap film CP3, the gate pattern GP, and the sidewall spacers SW.

As a result, the silicide film SI1 and the cap film CP3 formed on the memory gate electrode MG are removed. In addition, the upper surface of each of the cap film CP1, the memory gate electrode MG, and the gate pattern GP, which are recessed by the polishing process, are exposed from the interlayer dielectric film IL and the sidewall spacer SW. At this time, the upper surface of each of the cap film CP1, the memory gate electrode MG, the gate pattern GP, the sidewall spacers SW, and the interlayer dielectric film IL are flush with one another and are positioned at substantially the same height.

That is, the polishing process is performed so as not to completely remove the cap film CP1 and not to expose the upper surface of the control gate electrode CG. Since the position of the boundary between the control gate electrode CG and the cap film CP1 becomes lower than the position of the upper surface of the memory gate electrode MG prior to the polishing process, only the upper surface of the memory gate electrode MG can be exposed among the control gate electrode CG and the memory gate electrode MG.

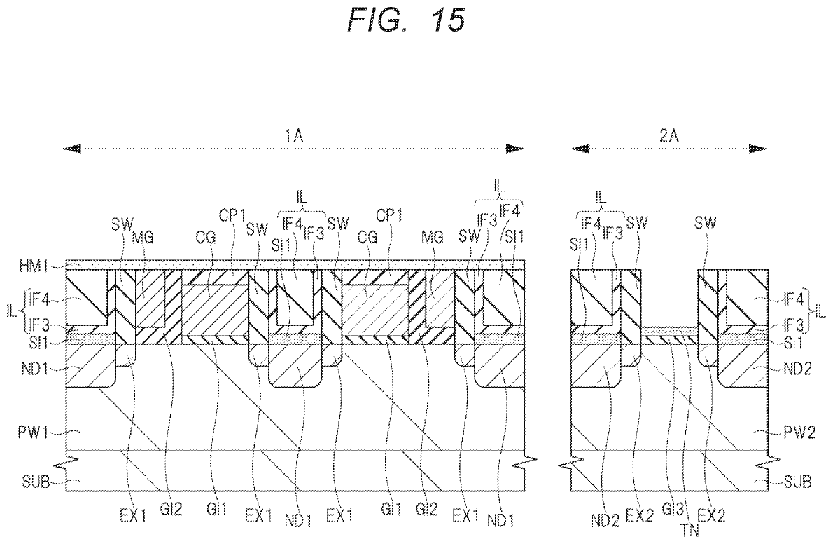

As shown in FIG. 15, first, a hard mask HM1 covering the region 1A and the region 2A is formed. The hard mask HM1 is, for example, a silicon nitride film, and can be formed using, for example, the CVD method. Next, the hard mask HM1 in the region 2A is selectively removed using the photolithography technique and the etching process. Next, the gate pattern GP is removed by a wet etching process. As a result, a trench is formed on the gate dielectric film GI3. At this time, since the metal film TN functions as an etching stopper, the gate dielectric film GI3 formed under the metal film TN is protected.

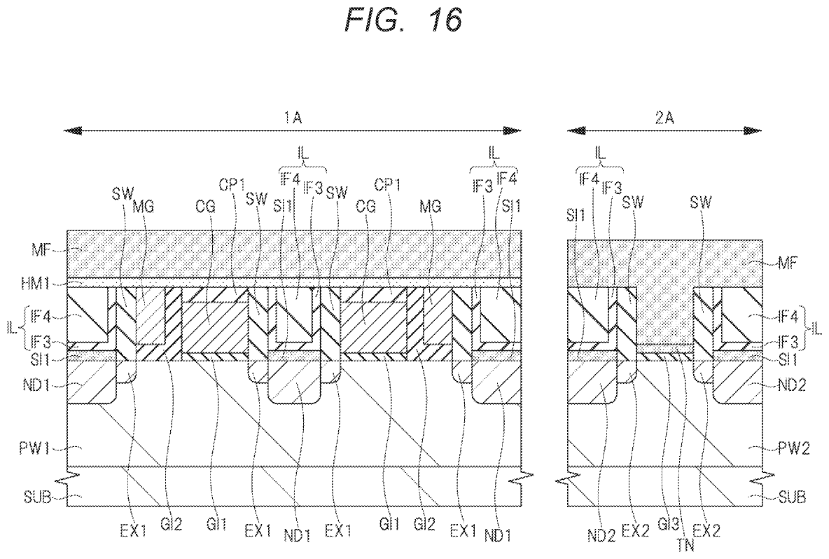

As shown in FIG. 16, a metal film MF is formed on the hard mask HM1 in the region 1A and on the interlayer dielectric film IL in the region 2A using, for example, the CVD method or a sputtering method so as to fill the trench on the gate dielectric film GI3.

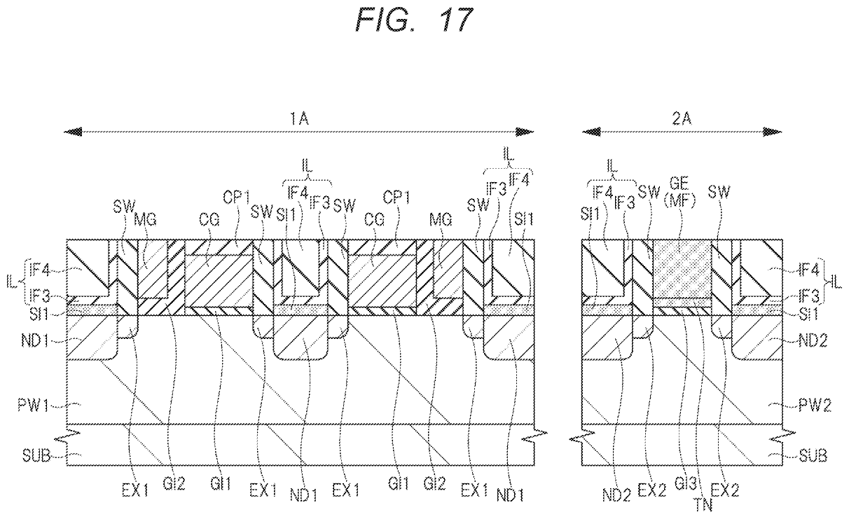

As shown in FIG. 17, the metal film MF and the hard mask HM1 are removed by the polishing process using the CMP method. The gate electrode GE including the remaining metal film MF is formed in the trench on the gate dielectric film GI3.

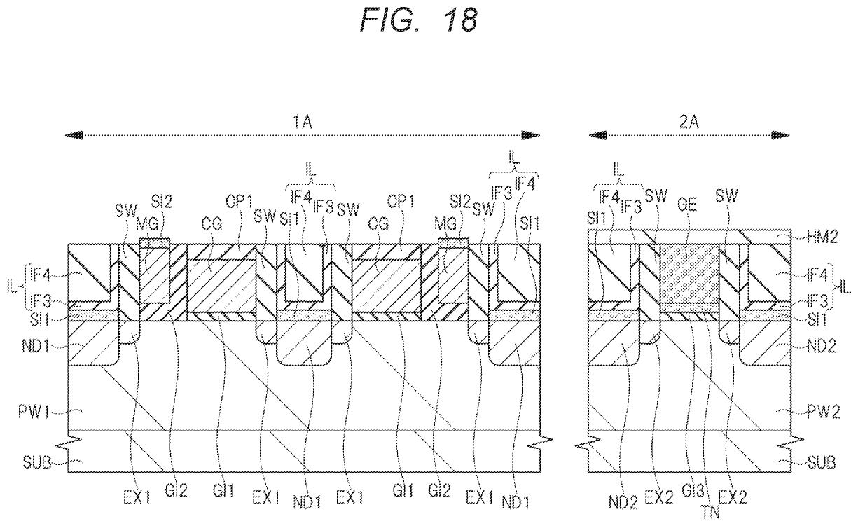

As shown in FIG. 18, first, a hard mask HM2 covering the region 1A and the region 2A is formed. The hard mask HM2 is, for example, a silicon oxide film, and can be formed using, for example, the CVD method. Next, the hard mask HM2 in the region 1A is selectively removed using the photolithography technique and the etching process.

Next, the silicide film SI2 is formed on the upper surface of the memory gate electrode MG by the same method as the method of forming the silicide film SI1. At this time, the silicide film SI2 is formed in a state where the cap film CP1 remains on the control gate electrode CG. Thereafter, the hard mask HM2 may be removed by the wet etching process or the like, or the hard mask HM2 may remain as a part of the upper interlayer dielectric film. Thus, the structure shown in FIG. 2 is obtained.

The positions of the upper surfaces of the cap film CP1, the silicide film SI2, the gate electrode GE, the sidewall spacers SW, and the interlayer dielectric film IL align with one another within a range of 10 nm or less. For example, when the position of the upper surface of the sidewall spacer SW is the highest and the position of the upper surface of the silicide film SI2 is the lowest, the difference between the position of the upper surface of the sidewall spacer SW and the position of the upper surface of the silicide film SI2 is 10 nm or less.

As described above, according to the manufacturing method of the first embodiment, the silicide film SI2 can be formed only on the upper surface of the memory gate electrode MG among the control gate electrode CG and the memory gate electrode MG.

Although not shown here, the region 1A and the region 2A are covered with the other interlayer dielectric film, and wirings are formed in the other interlayer dielectric film. Contact holes are formed in the other interlayer dielectric film, the interlayer dielectric film IL and the cap film CP1, and plug layers are formed in the contact holes, whereby the control gate electrode CG, the memory gate electrode MG, the gate electrode GE, the diffusion region ND1, and the diffusion region ND2 are electrically connected to wirings.

The dielectric film IF3 is formed of a material different from the material configuring the other interlayer dielectric film and the dielectric film IF4. Therefore, when the contact holes are formed in the other interlayer dielectric film and the dielectric film IF4, the dielectric film IF3 functions as an etching stopper.

### Second Embodiment

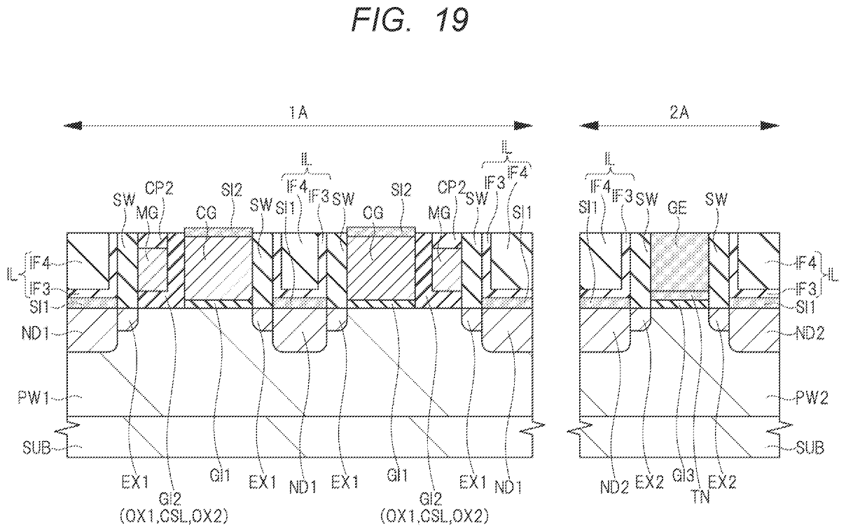

A semiconductor device 100 in the second embodiment will be described below with reference to FIG. 19. Note that, in the following description, differences from the first embodiment will be mainly described, and the description of overlapping points with the first embodiment will be omitted.

In the second embodiment, the silicide film SI2 is formed only on the upper surface of the control gate electrode CG among the control gate electrode CG and the memory gate electrode MG. A cap film CP2 formed of a dielectric material is formed on the upper surface of the memory gate electrode MG. The cap film CP2 is, for example, a silicon nitride film. The structure in the second embodiment is similar to the structure in the first embodiment except for these differences.

Also in the second embodiment, a short-circuit defect between the control gate electrode CG and the memory gate electrode MG can be suppressed, and the reliability of the semiconductor device 100 can be improved.

### Manufacturing Method of Semiconductor Device in Second Embodiment

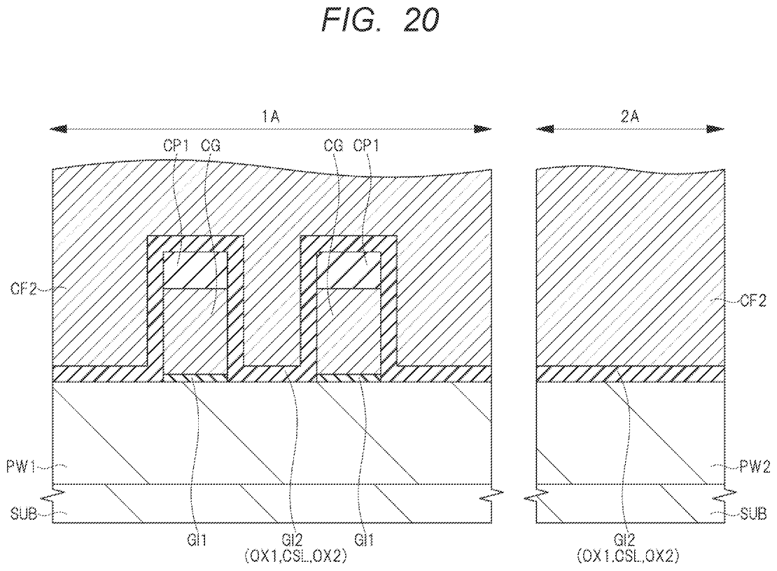

The manufacturing steps included in the manufacturing method of the semiconductor device 100 in the second embodiment will be described below with reference to FIGS. 20 to 34. Note that the same manufacturing steps as those of the first embodiment will not be described to some extent.

The manufacturing steps until the step of forming the gate dielectric film GI2 in the second embodiment is the same as the manufacturing steps until the step of forming the gate dielectric film GI2 of FIG. 5 in the first embodiment. FIG. 20 shows a step of forming the conductive film CF2.

As shown in FIG. 20, in the region 1A and the region 2A, the conductive film CF2 for the memory gate electrode MG is formed on the gate dielectric film GI2 using, for example, the CVD method. In the second embodiment, the conductive film CF2 is thicker than the conductive film CF2 in the first embodiment and is deposited to a position higher than the gate dielectric film GI2 on the cap film CP1.

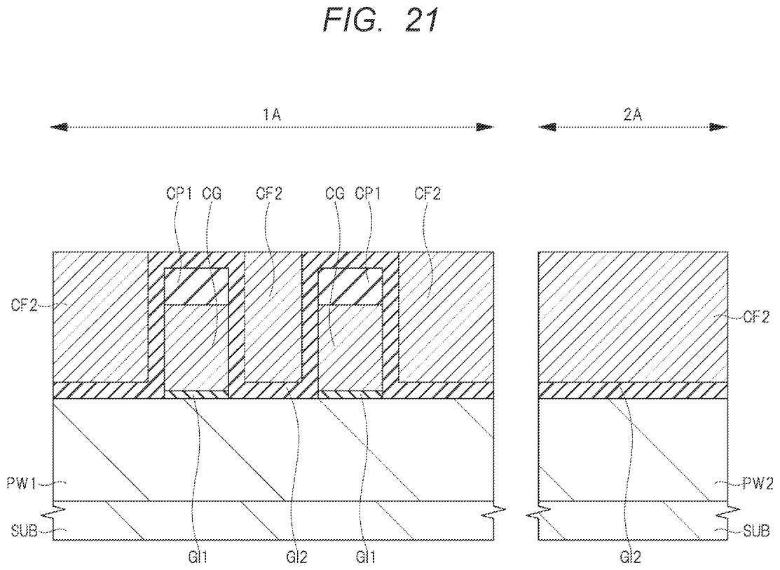

As shown in FIG. 21, the polishing process using the CMP method is performed to the conductive film CF2 using the gate dielectric film GI2 as an etching stopper. Thus, the position of the upper surface of the conductive film CF2 becomes substantially the same as the position of the upper surface of the gate dielectric film GI2 on the cap film CP1.

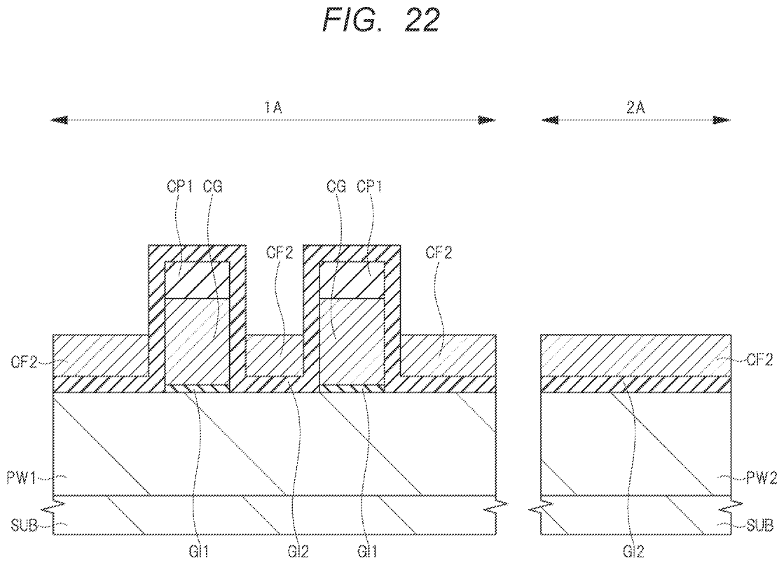

As shown in FIG. 22, the conductive film CF2 is recessed by performing an isotropic etching process to the conductive film CF2. Accordingly, the position of the upper surface of the conductive film CF2 becomes lower than the position of the boundary between the control gate electrode CG and the cap film CP1.

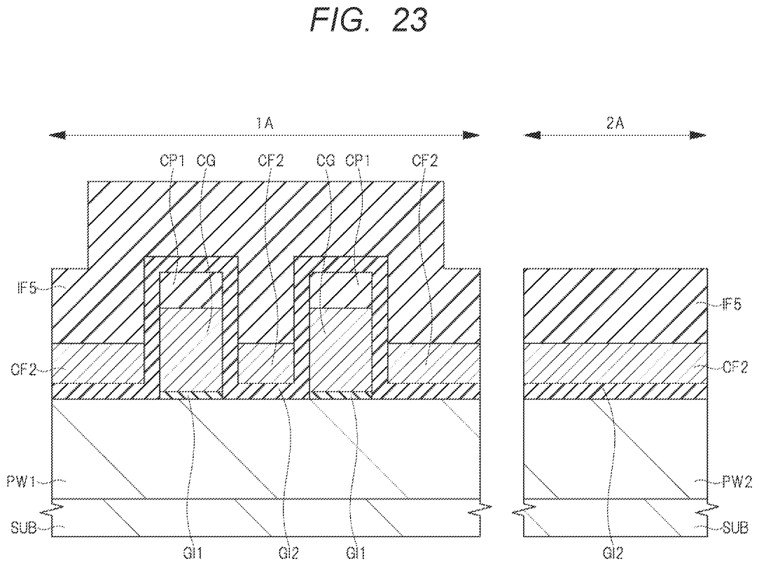

As shown in FIG. 23, a dielectric film IF5 is formed on the upper surface of the conductive film CF2 so as to cover the gate dielectric film GI2 using, for example, the CVD method. The dielectric film IF5 is, for example, a silicon nitride film.

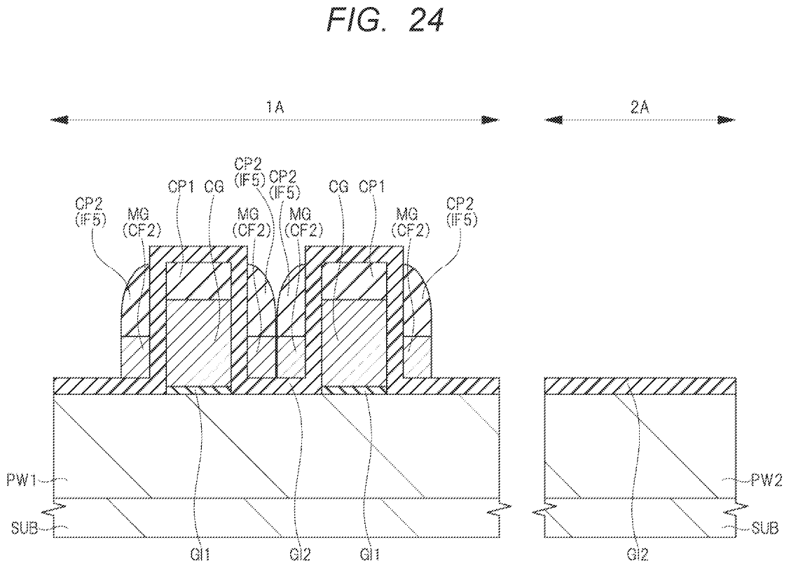

As shown in FIG. 24, first, the anisotropic etching process is performed to the dielectric film IF5 to form the sidewall-shaped cap film CP2 in the region 1A. All of the dielectric film IF5 in the region 2A is removed. Next, the conductive film CF2 exposed from the dielectric film IF5 is removed by performing the anisotropic etching process using the dielectric film IF5 as a mask. As a result, the remaining conductive film CF2 is formed as the memory gate electrode MG.

As described above, the memory gate electrode MG and the cap film CP2 located on the memory gate electrode MG are formed on the gate dielectric film GI2 so as to be adjacent to the control gate electrode CG and the cap film CP1 via the gate dielectric film GI2.

At this time, the position of the boundary between the memory gate electrode MG and the cap film CP2 becomes lower than the position of the boundary between the control gate electrode CG and the cap film CP1.

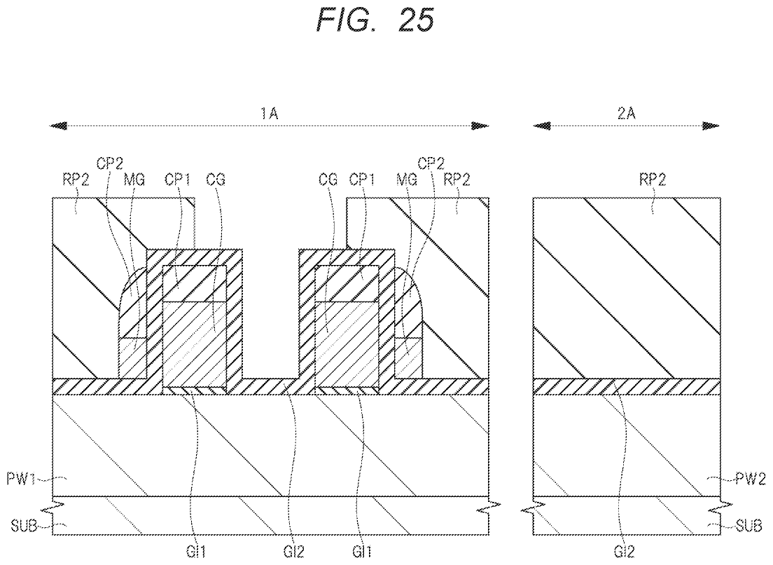

As shown in FIG. 25, first, a resist pattern RP2 covering a part of the region 1A and the region 2A is formed. Next, the etching process is performed using the resist pattern RP2 as a mask to remove the cap film CP2 and the memory gate electrode MG formed on the other side surface of the control gate electrode CG. Thereafter, the resist pattern RP2 is removed by an ashing process.

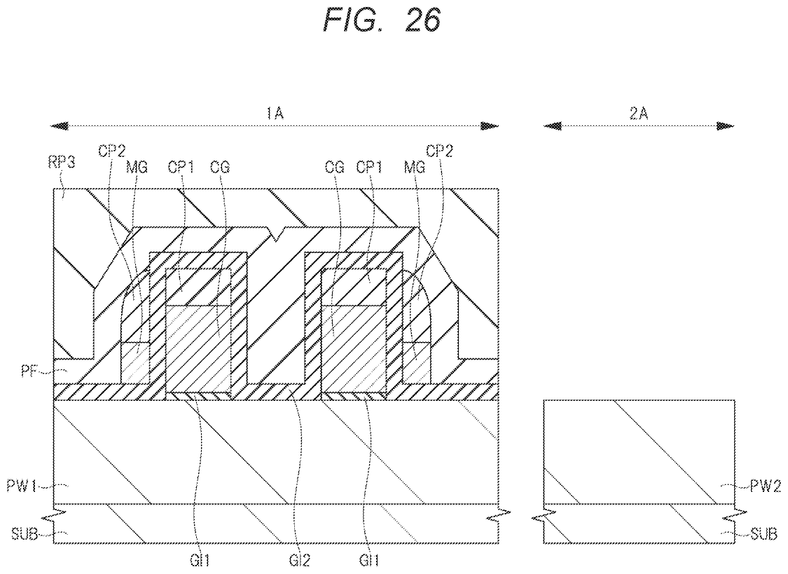

As shown in FIG. 26, first, the protective film PF is formed on the gate dielectric film GI2 so as to cover the cap film CP2 using, for example, the CVD method. Next, a resist pattern RP3 is formed on the protective film PF. Next, the etching process is performed using the resist pattern RP3 as a mask to remove the protective film PF and the gate dielectric film GI2 in the region 2A. Thereafter, the resist pattern RP3 is removed by ashing.

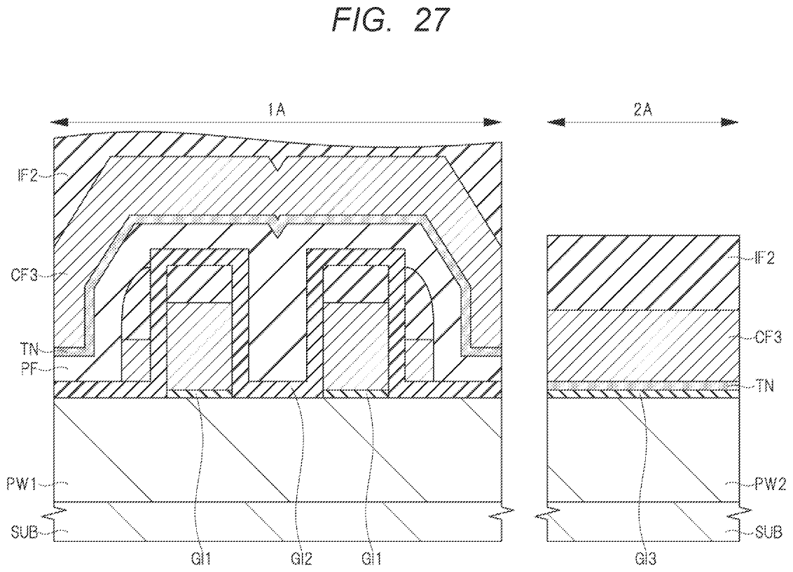

As shown in FIG. 27, first, the gate dielectric film GI3 is formed on the upper surface of the semiconductor substrate SUB in the region 2A using, for example, the thermal oxidation method. Next, the metal film TN and the conductive film CF3 are sequentially formed on the protective film PF in the region 1A and on the gate dielectric film GI3 in the region 2A using, for example, the CVD method. Next, the dielectric film IF2 is formed on the conductive film CF3 using, for example, the CVD method.

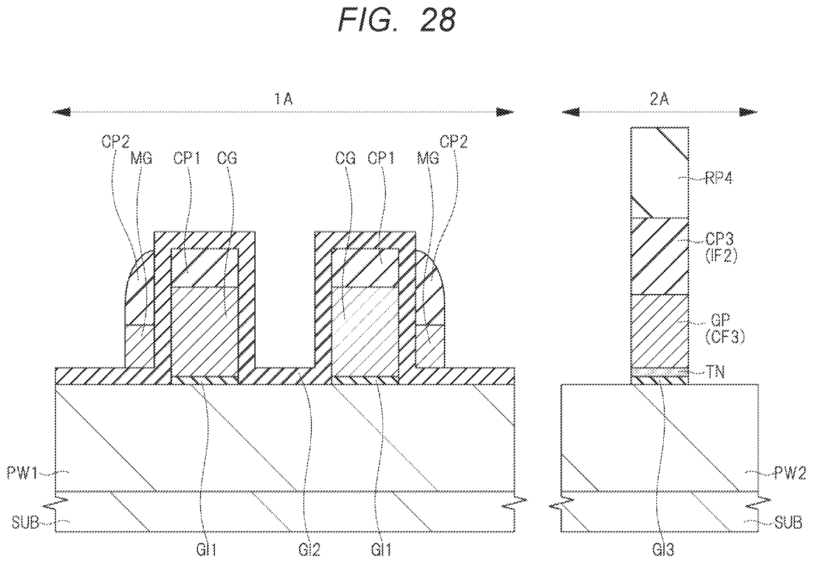

As shown in FIG. 28, first, a resist pattern RP4 is formed on the dielectric film IF2 in the region 2A. Next, the dielectric film IF2, the conductive film CF3, the metal film TN, and the gate dielectric film GI3 are patterned by performing the etching process using the resist pattern RP4 as a mask.

The patterned dielectric film IF2 functions as the cap film CP3, and the patterned conductive film CF3 functions as the gate pattern GP. The patterned metal film TN functions as a part of the gate electrode GE described later. At this time, in the region 1A, the dielectric film IF2, the conductive film CF3, the metal film TN, and the protective film PF are removed. Thereafter, the resist pattern RP4 is removed by ashing. The gate pattern GP is formed such that the position of the upper surface of the gate pattern GP is higher than the position of the boundary between the memory gate electrode MG and the cap film CP2. Thus, when the upper surface of the gate pattern GP is exposed by the polishing process described later, the upper surface of the memory gate electrode MG is not exposed.

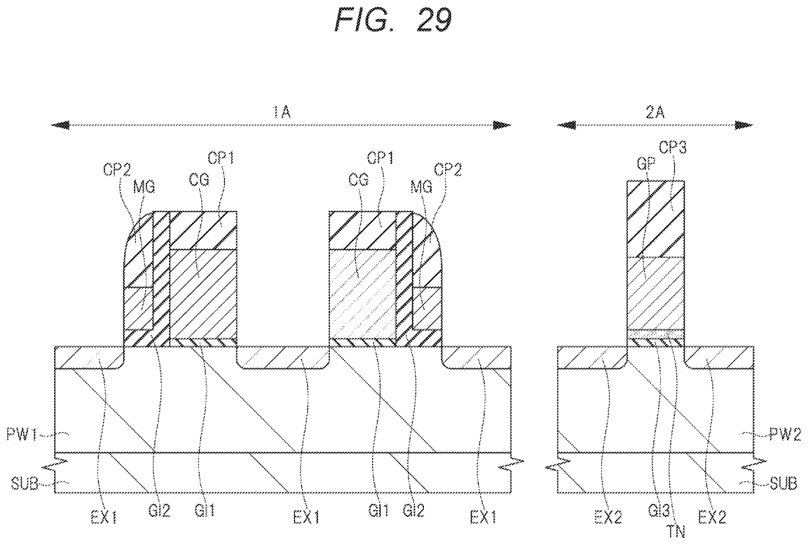

As shown in FIG. 29, first, the gate dielectric film GI2 not covered with the memory gate electrode MG is removed by the etching process. At this time, the gate dielectric film GI2 formed between the memory gate electrode MG and the control gate electrode CG remains.

Next, the n-type extension region EX1 is formed in the semiconductor substrate SUB (well region PW1) in the region 1A and the n-type extension region EX2 is formed in the semiconductor substrate SUB (well region PW2) in the region 2A using the photolithography technique and the ion implantation method.

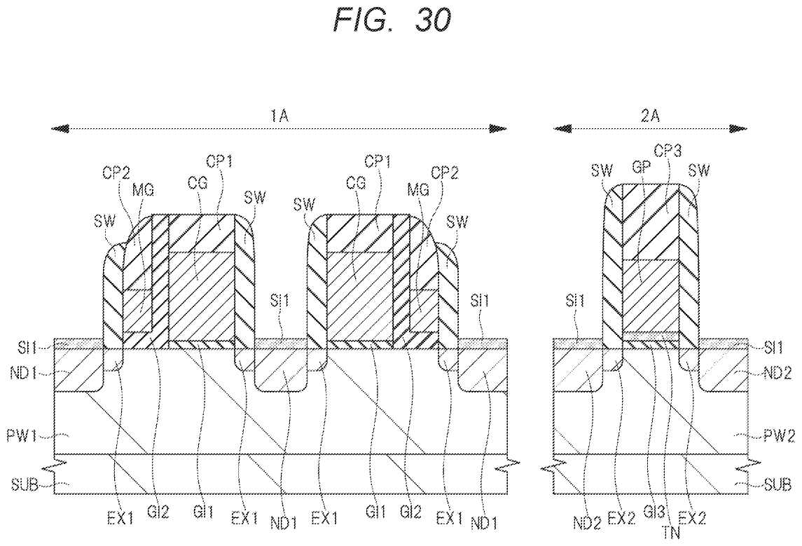

As shown in FIG. 30, first, the sidewall spacer SW is formed on the other side surface of the control gate electrode CG, the other side surface of the memory gate electrode MG, and on each of the side surfaces of the gate pattern GP.

Next, the n-type diffusion region ND1 is formed in the semiconductor substrate SUB (well region PW1) in the region 1A, and the n-type diffusion region ND2 is formed in the semiconductor substrate SUB (well region PW2) in the region 2A using the photolithography technique and the ion implantation method.

Next, the silicide film SI1 is formed on the upper surface of each of the diffusion region ND1 and the diffusion region ND2 using the Salicide (Self Aligned Silicide) technique similar to that of the first embodiment.

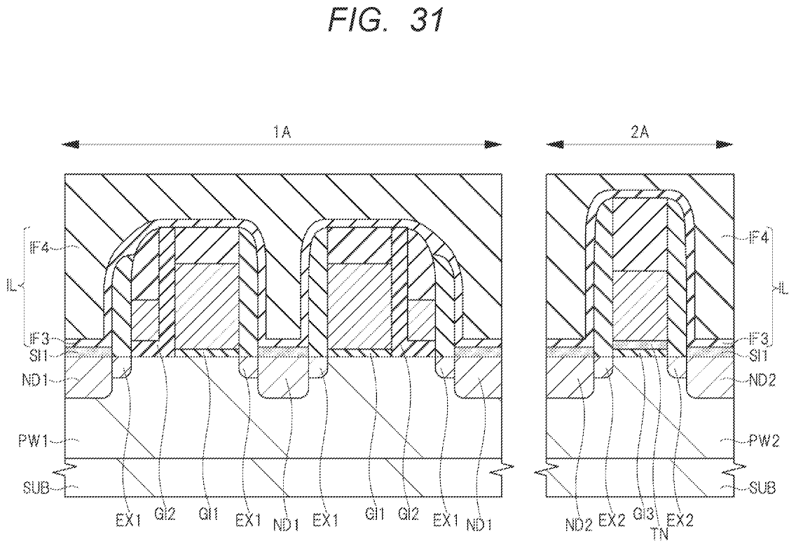

As shown in FIG. 31, the interlayer dielectric film IL is formed on the upper surface of the semiconductor substrate SUB so as to cover the cap film CP1, the cap film CP2, the gate pattern GP, and the sidewall spacer SW. The interlayer dielectric film IL is formed by forming the dielectric film IF3 and then forming the dielectric film IF4 on the dielectric film IF3.

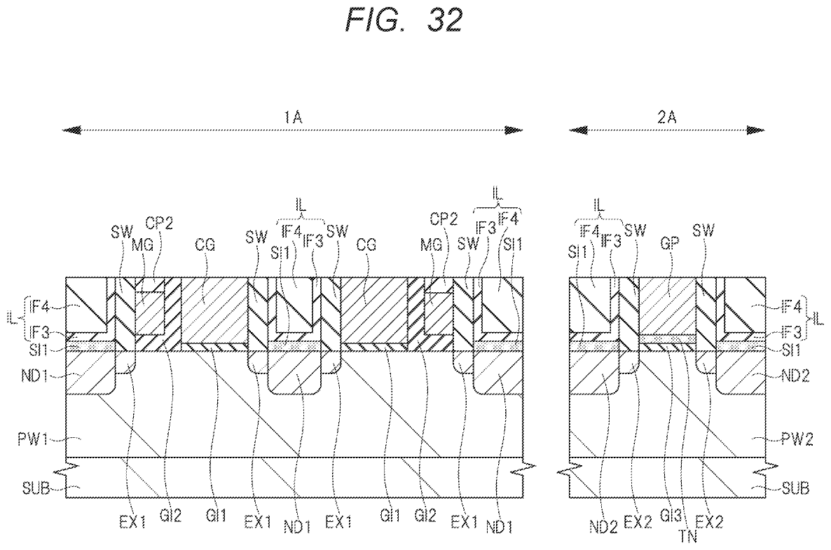

As shown in FIG. 32, the polishing process using the CMP method is performed to the interlayer dielectric film IL, the cap film CP1, the control gate electrode CG, the cap film CP2, the cap film CP3, the gate pattern GP, and the sidewall spacer SW.

Thus, the cap film CP1 and the cap film CP3 are removed. In addition, the upper surface of each of the control gate electrode CG, the cap film CP2, and the gate pattern GP, which are recessed by the polishing process, are exposed from the interlayer dielectric film IL and the sidewall spacer SW. At this time, the upper surface of each of the control gate electrode CG, the cap film CP2, the gate pattern GP, the sidewall spacer SW, and the interlayer dielectric film IL is flush with one another and is positioned at substantially the same height.

That is, the polishing process is performed so as not to completely remove the cap film CP2 and not to expose the upper surface of the memory gate electrode MG. Since the position of the boundary between the memory gate electrode MG and the cap film CP2 becomes lower than the position of the boundary between the control gate electrode CG and the cap film CP1 prior to the polishing process, only the upper surface of the control gate electrode CG can be exposed among the control gate electrode CG and the memory gate electrode MG.

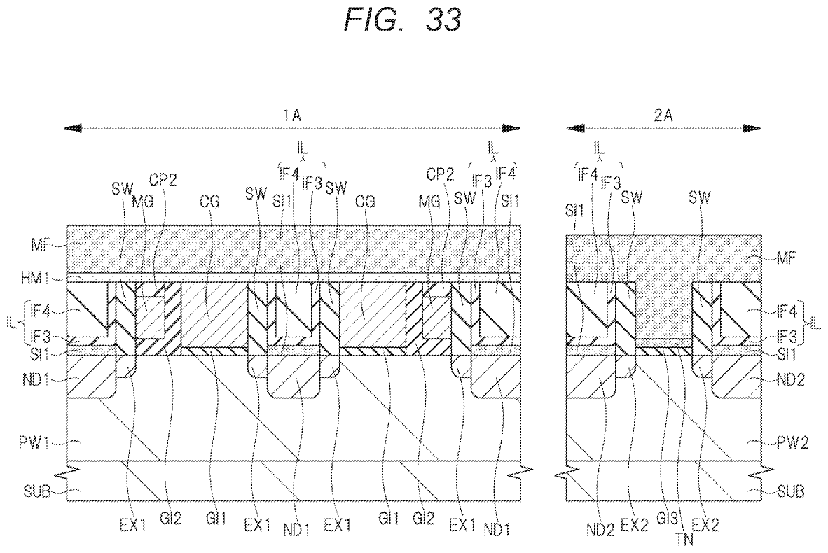

As shown in FIG. 33, first, the hard mask HM1 covering the region 1A and the region 2A is formed. Next, the hard mask HM1 in the region 2A is selectively removed using the photolithography technique and the etching process. Next, the gate pattern GP is removed by the wet etching process. As a result, the trench is formed on the gate dielectric film GI3. Next, the metal film MF is formed on the hard mask HM1 in the region 1A and on the interlayer dielectric film IL in the region 2A so as to fill the trench on the gate dielectric film GI3.

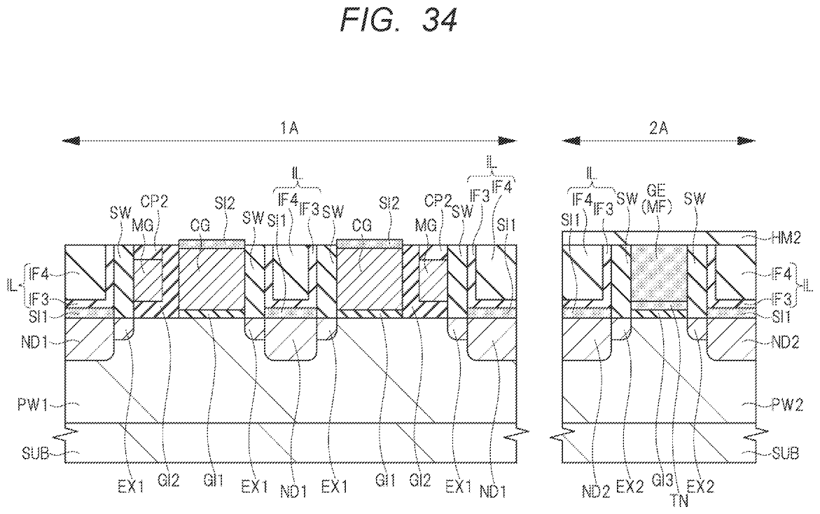

As shown in FIG. 34, the metal film MF and the hard mask HM1 are removed using by the polishing process using the CMP method. The gate electrode GE including the remaining metal film MF is formed in the trench on the gate dielectric film GI3.

Next, the hard mask HM2 covering the region 1A and the region 2A is formed. Next, the hard mask HM2 in the region 1A is selectively removed using the photolithography technique and the etching process. Next, the silicide film SI2 is formed on the upper surface of the control gate electrode CG using the same method as the method of forming the silicide film SI1. At this time, the silicide film SI2 is formed in a state where the cap film CP2 remains on the memory gate electrode MG. Thereafter, the hard mask HM2 may be removed, but the hard mask HM2 may remain as a part of the upper interlayer dielectric film. Thus, the structure shown in FIG. 19 is obtained.

The positions of the upper surfaces of the cap film CP2, the silicide film SI2, the gate electrode GE, the sidewall spacer SW, and the interlayer dielectric film IL align with one another within a range of 10 nm or less. For example, when the position of the upper surface of the sidewall spacer SW is the highest and the position of the upper surface of the silicide film SI2 is the lowest, the difference between the position of the upper surface of the sidewall spacer SW and the position of the upper surface of the silicide film SI2 is 10 nm or less.

As described above, according to the manufacturing method of the second embodiment, the silicide film SI2 can be formed only on the upper surface of the control gate electrode CG among the control gate electrode CG and the memory gate electrode MG.

Although the present invention has been described in detail based on the above-described embodiments, the present invention is not limited to the above-described embodiments, and can be variously modified without departing from the gist thereof.

What is claimed is:

1. A semiconductor device comprising:
a first gate dielectric film formed on an upper surface of a semiconductor substrate;
a first gate electrode formed on the first gate dielectric film;
a second gate dielectric film formed on the upper surface of the semiconductor substrate and on one side surface of the first gate electrode and including a charge storage layer;
a second gate electrode formed on the second gate dielectric film such that one side surface of the second gate electrode faces the one side surface of the first gate electrode via the second gate dielectric film;
a first sidewall spacer formed on the other side surface of the first gate electrode;
a first interlayer dielectric film formed on the other side surface of the first gate electrode via the first sidewall spacer;
a second sidewall spacer formed on the other side surface of the second gate electrode; and
a second interlayer dielectric film formed on the other side surface of the second gate electrode via the second sidewall spacer,
wherein a cap film formed of a dielectric material is formed on an upper surface of one of the first gate electrode and the second gate electrode,
wherein a silicide film is formed on an upper surface of the other of the first gate electrode and the second gate electrode, and
wherein an upper surface of the cap film and an upper surface of the silicide film are exposed from the first sidewall spacer, the second sidewall spacer, the first interlayer dielectric film and the second interlayer dielectric film.

2. The semiconductor device according to claim 1,
wherein the semiconductor substrate includes a first region where a nonvolatile memory cell is formed and a second region where a first MISFET is formed,
wherein the nonvolatile memory cell includes the first gate dielectric film. the first gate electrode, the second gate dielectric film, the second gate electrode, the cap film and the silicide film,
wherein the first MISFET includes:
a third gate dielectric film formed on the upper surface of the semiconductor substrate in the second region; and
a third gate electrode formed on the third gate dielectric film and including a metal film,
wherein a third sidewall spacer is formed on one side surface of the third gate electrode,
wherein a third interlayer dielectric film is formed on the one side surface of the third gate electrode via the third sidewall spacer,
wherein a fourth sidewall spacer is formed on the other side surface of the third gate electrode,
wherein a fourth interlayer dielectric film formed on the other side surface of the third gate electrode via the fourth sidewall spacer, and
wherein an upper surface of the third gate electrode is exposed from the third sidewall spacer, the fourth sidewall spacer, the third interlayer dielectric film and the fourth interlayer dielectric film.

3. The semiconductor device according to claim 1,
wherein a polishing process is performed to the other of the first gate electrode and the second gate electrode, the first sidewall spacer, the second sidewall spacer, the first interlayer dielectric film, the second interlayer dielectric film, and the cap film.

4. The semiconductor device according to claim 1,
wherein a position of an upper surface of each of the first sidewall spacer, the second sidewall spacer, the first interlayer dielectric film, the second interlayer dielectric film, the cap film and the silicide film aligns with one another within a range of 10 nm or less.

5. The semiconductor device according to claim 1,
wherein the cap film is formed on the upper surface of the first gate electrode, and
wherein the silicide film is formed on the upper surface of the second gate electrode.

6. The semiconductor device according to claim 1,
wherein the silicide film is formed on the upper surface of the first gate electrode, and
wherein the cap film is formed on the upper surface of the second gate electrode.

7. A method of manufacturing a semiconductor device, the method comprising:
(a) forming a first gate dielectric film on an upper surface of a semiconductor substrate;
(b) forming a first gate electrode on the first gate dielectric film;
(c) forming a first cap film formed of a dielectric material on the first gate electrode;
(d) forming a second gate dielectric film on the upper surface of the semiconductor substrate, on a side surface of the first gate electrode and on a side surface of the first cap film, the second gate dielectric film including a charge storage layer;
(e) forming a second gate electrode on the second gate dielectric film so as to be adjacent to the first gate electrode and the first cap film via the second gate dielectric film;
(f) forming an interlayer dielectric film on the upper surface of the semiconductor substrate so as to cover the first cap film and the second gate electrode;
(g) performing a polishing process to the interlayer dielectric film, the first cap film and the second gate electrode, thereby exposing an upper surface recessed by the polishing process of each of the first cap film and the second gate electrode from the interlayer dielectric film; and
(h) after the (g), forming a silicide film on the upper surface of the second gate electrode in a state where the first cap film remains.

8. The method according to claim 7,
wherein in the (e), a position of a boundary between the first gate electrode and the first cap film is lower than a position of the upper surface of the second gate electrode.

9. The method according to claim 7,
wherein the semiconductor substrate includes a first region where a nonvolatile memory cell is formed and a second region where a first MISFET is formed, and
wherein the nonvolatile memory cell includes the first gate dielectric film. the first gate electrode, the first cap film, the second gate dielectric film, the second gate electrode and the silicide film.

10. The method according to claim 9, comprising:
(i) before the (f), forming a third gate dielectric film on the upper surface of the semiconductor substrate in the second region; and
(j) between the (i) and the (f), forming a gate pattern on the third gate dielectric film,
wherein in the (f), the interlayer dielectric film is formed to cover the gate pattern, and
wherein in the (g), by performing the polishing process to the gate pattern, a recessed upper surface of the gate pattern is exposed from the interlayer dielectric film.

11. The method according to claim 10,
wherein in the (j), a position of the upper surface of the gate pattern is higher than the position of the boundary between the first gate electrode and the first cap film.

12. The method according to claim 11, comprising:
(k) after the (g), removing the gate pattern to form a trench; and
(l) after the (k), filling the trench with a metal film to form a third gate electrode including the metal film,
wherein the first MISFET includes the third gate dielectric film and the third gate electrode.

13. A method of manufacturing a semiconductor device, the method comprising:
(a) forming a first gate dielectric film on an upper surface of a semiconductor substrate;
(b) forming a first gate electrode on the first gate dielectric film;
(c) forming a first cap film formed of a dielectric material on the first gate electrode;
(d) forming a second gate dielectric film on the upper surface of the semiconductor substrate, on a side surface of the first gate electrode and on a side surface of the first cap film, the second gate dielectric film including a charge storage layer;
(e) forming a second gate electrode and a second cap film on the second gate dielectric film so as to be adjacent to the first gate electrode and the first cap film via the second gate dielectric film, the second cap film being located on the second gate electrode and formed of a dielectric material;
(f) forming an interlayer dielectric film on the upper surface of the semiconductor substrate so as to cover the first cap film and the second cap film;
(g) performing a polishing process to the interlayer dielectric film, the first cap film, the first gate electrode and the second cap film, thereby removing the first cap film and exposing an upper surface recessed by the polishing process of each of the first gate electrode and the second cap film from the interlayer dielectric film; and
(h) after the (g), forming a silicide film on the upper surface of the first gate electrode in a state where the second cap film remains.

14. The method according to claim 13,
wherein in the (e), a position of a boundary between the second gate electrode and the second cap film is lower than a position of a boundary between the first gate electrode and the first cap film.

15. The method according to claim 13,
wherein the semiconductor substrate includes a first region where a nonvolatile memory cell is formed and a second region where a first MISFET is formed, and
wherein the nonvolatile memory cell includes the first gate dielectric film. the first gate electrode, the silicide film, the second gate dielectric film, the second gate electrode and the second cap film.

16. The method according to claim 15,
(i) before the (f), forming a third gate dielectric film on the upper surface of the semiconductor substrate in the second region; and
(j) between the (i) and the (f), forming a gate pattern on the third gate dielectric film,
wherein in the (f), the interlayer dielectric film is formed to cover the gate pattern, and
wherein in the (g), by performing the polishing process to the gate pattern, a recessed upper surface of the gate pattern is exposed from the interlayer dielectric film.

17. The method according to claim 16,
wherein in the (j), a position of the upper surface of the gate pattern is higher than the position of the boundary between the second gate electrode and the second cap film.

18. The method according to claim 17,
(k) after the (g), removing the gate pattern to form a trench; and
(l) after the (k), filling the trench with a metal film to form a third gate electrode including the metal film,
wherein the first MISFET includes the third gate dielectric film and the third gate electrode.
